(19) United States
(12) Patent Application Publication
(10) Pub. No.: US 2021/0222288 A1
(43) Pub. Date: Jul. 22, 2021

(54) DEPOSITION APPARATUS FOR COATING A FLEXIBLE SUBSTRATE, METHOD OF COATING A FLEXIBLE SUBSTRATE AND FLEXIBLE SUBSTRATE HAVING A COATING

(71) Applicant: Applied Materials, Inc., Santa Clara, CA (US)

(72) Inventors: Christof KURTHEN, Bruckmühl (DE); Stefan HEIN, Blankenbach (DE); Reiner KUKLA, Hanau (DE); Neil MORRISON, Darmstadt (DE); Thomas DEPPISCH, Aschaffenburg (DE); Stefan LORENZ, Karlstein (DE); Edgar HABERKORN, Jossgrund (DE)

(21) Appl. No.: 16/308,365

(22) PCT Filed: Nov. 28, 2017
(86) PCT No.: PCT/EP2017/080692

§ 371 Date: Dec. 7, 2018

(51) Int. Cl. C23C 14/34; C23C 14/06; C23C 14/50; C23C 14/58; C23C 14/56

(52) U.S. Cl. CPC C23C 14/3414; C23C 14/0605; C23C 14/3435; C23C 14/562; C23C 14/5833; C23C 14/582; C23C 14/505

(57) ABSTRACT

A deposition apparatus for coating a flexible substrate is described. The deposition apparatus comprises a first spool chamber housing a storage spool for providing the flexible substrate, a deposition chamber arranged downstream from the first spool chamber, and a second spool chamber arranged downstream from the deposition chamber and housing a wind-up spool for winding the flexible substrate thereon after deposition. The deposition chamber comprises a coating drum for guiding the flexible substrate past a plurality of deposition units including at least one deposition unit having a graphite target. The coating drum is connected to a device for applying an electrical potential to the coating drum.

### TECHNICAL FIELD

Embodiments of the disclosure relate to thin-film deposition apparatuses and methods, particularly to apparatuses and methods for coating flexible substrates with thin layers. In particular, embodiments of the disclosure relate to roll-to-roll (R2R) deposition apparatuses and coating methods for coating a flexible substrate. More specifically, embodiments of the disclosure relate to apparatuses and methods for coating a flexible substrate with a stack of layers, e.g. for thin-film solar cell production, thin-film battery production, and flexible display production.

### BACKGROUND

Processing of flexible substrates, such as plastic films or foils, is in high demand in the packaging industry, semiconductor industries and other industries. Processing may consist of coating a flexible substrate with a material, such as a metal, a semiconductor and a dielectric material, etching and other processing actions conducted on a substrate for the respective applications. Systems performing this task generally include a coating drum, e.g. a cylindrical roller, coupled to a processing system with a roller assembly for transporting the substrate, and on which at least a portion of the substrate is coated.

For example, a coating process such as a CVD process or a PVD process, particularly a sputter process, can be utilized for depositing thin layers onto flexible substrates. Roll-to-roll deposition apparatuses are understood in that a flexible substrate of a considerable length, such as one kilometer or more, is uncoiled from a storage spool, coated with a stack of thin layers, and recoiled again on a wind-up spool. In particular, in the manufacture of thin film batteries, the display industry and the photovoltaic (PV) industry, roll-to-roll deposition systems are of high interest. For example, the increasing demand for flexible touch panel elements, flexible displays, and flexible PV modules results in an increasing demand for depositing suitable layers in R2R-coaters.

Further, there is a continuous demand for improved coating apparatuses and improved methods of coating a flexible substrate with which high quality layers and high quality layer stack systems can be produced. Improvements to the layers or layer stack systems being, for instance, having improved uniformity, improved product lifetime, and a lower number of defects per surface area.

In view of the above, a deposition apparatus for coating a flexible substrate as well as a method of coating a flexible substrate is provided, with which improved layers and improved layer stack systems can be provided when compared to conventional apparatuses and methods.

### SUMMARY

In light of the above, a deposition apparatus for coating a flexible substrate as well as a method of coating a flexible substrate according to the independent claims are provided. Further aspects, advantages, and features are apparent from the dependent claims, the description, and the accompanying drawings.

According to an aspect of the present disclosure, a deposition apparatus for coating a flexible substrate is provided. The deposition apparatus includes: a first spool chamber housing a storage spool for providing the flexible substrate, a deposition chamber arranged downstream from the first spool chamber, and a second spool chamber arranged downstream from the deposition chamber and housing a wind-up spool for winding the flexible substrate thereon after deposition. The deposition chamber includes a coating drum for guiding the flexible substrate past a plurality of deposition units including at least one deposition unit having a graphite target. The coating drum is connected to a device for applying an electrical potential to the coating drum.

According to a further aspect of the present disclosure, a deposition apparatus for coating a flexible substrate with a stack of layers including a diamond like carbon layer is provided. The deposition apparatus includes: a first spool chamber housing a storage spool for providing the flexible substrate, a deposition chamber arranged downstream from the first spool chamber, and a second spool chamber arranged downstream from the deposition chamber and housing a wind-up spool for winding the flexible substrate thereon after deposition. The deposition chamber includes a coating drum for guiding the flexible substrate past a plurality of deposition units including at least one sputter deposition unit having a graphite target. The coating drum is configured for providing an electrical potential to a substrate guiding surface of the coating drum, the electrical potential being a middle frequency potential having a frequency of 1 kHz to 100 kHz.

According to another aspect of the present disclosure, a method of coating a flexible substrate with a carbon layer is provided. The method includes: unwinding the flexible substrate from a storage spool provided in a first spool chamber; depositing a carbon layer on the flexible substrate while guiding the flexible substrate using a coating drum provided in a deposition chamber; applying an electrical potential to the coating drum; and winding the flexible substrate on a wind-up spool provided in a second spool chamber after deposition.

According to a further aspect of the present disclosure, a flexible substrate having a coating with one or more layers being produced by a method according to embodiments described herein is provided.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1 shows a sectional schematic view of a deposition apparatus according to embodiments described herein;

FIG. 2 shows a sectional schematic view of a deposition apparatus according to further embodiments described herein;

FIG. 3 shows an enlarged schematic view of a part of a deposition chamber that may be used in some of the embodiments described herein;

FIG. 4 shows a schematic view of an AC sputter source that may be used in some of the embodiments described herein;

FIG. 5 shows a schematic view of a DC sputter source that may be used in some of the embodiments described herein;

FIG. 6 shows a schematic view of a double DC planar cathode sputter source that may be used in some of the embodiments described herein;

FIGS. 7A and 7B show flowcharts for illustrating a method of coating a flexible substrate according to embodiments described herein; and

FIGS. 8A and 8B show flexible substrates being coated with one or more layers including at least one carbon layer being produced by a method according to embodiments described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

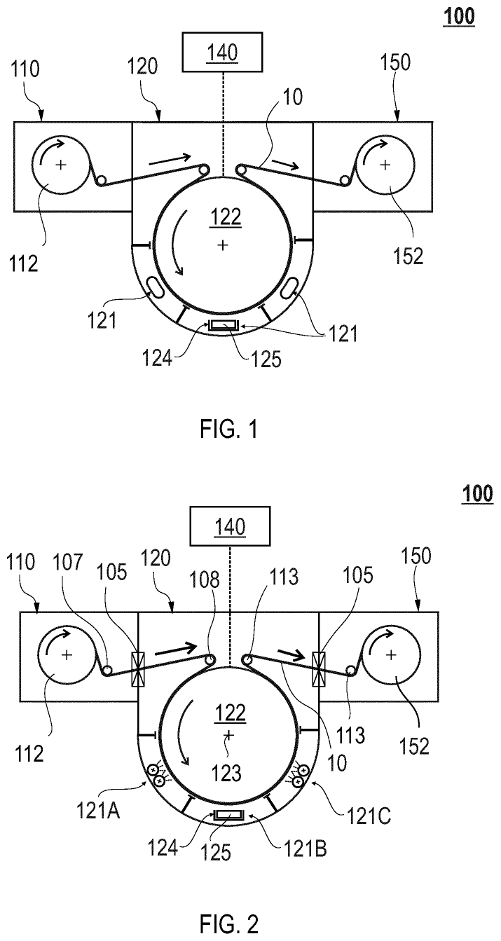

With exemplary reference to FIG. 1, a deposition apparatus 100 for coating a flexible substrate 10 according to the present disclosure is described. According to embodiments which can be combined with any other embodiments described herein, the deposition apparatus 100 includes a first spool chamber 110 housing a storage spool 112 for providing the flexible substrate 10. Further, the deposition apparatus 100 includes a deposition chamber 120 arranged downstream from the first spool chamber 110. Additionally, the deposition apparatus 100 includes a second spool chamber 150 arranged downstream from the deposition chamber 120 and housing a wind-up spool 152 for winding the flexible substrate 10 thereon after deposition. The deposition chamber 120 includes a coating drum 122 for guiding the flexible substrate past a plurality of deposition units 121. The plurality of deposition units 121 include at least one deposition unit 124 having a graphite target 125. Further, as exemplarily shown in FIG. 1, the coating drum is connected to a device 140 for applying an electrical potential to the coating drum.

Accordingly, embodiments of the deposition apparatus as described herein are improved when compared to conventional deposition apparatuses. In particular, the deposition apparatus beneficially provides for coating a flexible substrate with a carbon layer. More specifically, the deposition apparatus beneficially provides for coating a flexible substrate with a stack of layers having one or more carbon layers. Further, providing the coating drum with an electrical potential has the advantage that electrons or ions, e.g. from a plasma provided in the deposition chamber, are accelerated towards the coating drum and hit the layer deposited on the substrate. In other words, embodiments of the deposition apparatus as described herein are configured for providing an ion bombardment and/or electron bombardment on a layer deposited on the substrate, which beneficially has the effect that the deposited layer can be densified. It has been found that a densification of a deposited carbon layer by ion bombardment and/or electron bombardment beneficially results in a diamond like carbon (DLC) layer. Accordingly, embodiments of the deposition apparatus as described herein have the advantage that a stack of layers including one or more DLC-layers can be deposited on a flexible substrate.

In the present disclosure, a “deposition apparatus” can be understood as an apparatus configured for depositing material on a substrate, particularly a flexible substrate. In particular, the deposition apparatus is a roll-to-roll (R2R) deposition configured for coating a flexible substrate with a stack of layers. More specifically, the deposition apparatus can be a vacuum deposition apparatus having at least one vacuum chamber, particularly a vacuum deposition chamber. For instance, the deposition apparatus may be configured for a substrate length of 500 m or more, 1000 m or more, or several kilometers. The substrate width can be 300 mm or more, particularly 500 mm or more, more particularly 1 m or more. Further, the substrate width can be 3 m or less, particularly 2 m or less.

In the present disclosure, a “flexible substrate” can be understood as a bendable substrate. For instance, the “flexible substrate” can be a “foil” or a “web”. In the present disclosure the term “flexible substrate” and the term “substrate” may be synonymously used. For example, the flexible substrate as described herein may include materials like PET, HC-PET, PE, PI, PU, TaC, OPP, CPP, one or more metals, paper, combinations thereof, and already coated substrates like Hard Coated PET (e.g. HC-PET, HC-TaC) and the like. In some embodiments, the flexible substrate is a COP substrate provided with an index matched (IM) layer on both sides thereof. For example, the substrate thickness can be 20 μm or more and 1 mm or less, particularly from 50 μm to 200 μm.

In the present disclosure, a “deposition chamber” can be understood as chamber having at least one deposition unit for depositing material on a substrate. In particular, the deposition chamber may be a vacuum chamber, e.g. a vacuum deposition chamber. The term “vacuum”, as used herein, can be understood in the sense of a technical vacuum having a vacuum pressure of less than, for example, 10 mbar. Typically, the pressure in a vacuum chamber as described herein may be between 10⁻⁵ mbar and about 10⁻⁸ mbar, more typically between 10⁻⁵ mbar and 10⁻⁷ mbar, and even more typically between about 10⁻⁶ mbar and about 10⁻⁷ mbar.

In the present disclosure, a “deposition unit” can be understood as a unit or device configured for depositing material on a substrate. For example, the deposition unit may be a sputter deposition unit, as described herein. However, the deposition apparatus described herein is not limited to sputter deposition, and other deposition units may additionally be used. For example, in some implementations, CVD deposition units, evaporation deposition units, PECVD deposition units or other deposition units may be utilized.

In the present disclosure, a “coating drum” can be understood as a drum or a roller having a substrate support surface for contacting the flexible substrate. In particular, the coating drum can be rotatable about a rotation axis and may include a substrate guiding region. Typically, the substrate guiding region is a curved substrate support surface, e.g. a cylindrically symmetric surface, of the coating drum. The curved substrate support surface of the coating drum may be adapted to be (at least partly) in contact with the flexible substrate during operation of the deposition apparatus.

In the present disclosure, a “device for applying an electrical potential” can be understood as a device being configured to apply an electrical potential to the coating drum, particularly to the substrate support surface of the coating drum. In particular, the device for applying an electrical potential as described herein can be configured to provide a middle frequency (MF) electrical potential. For instance, the middle frequency (MF) electrical potential can be from 1 kHz to 100 kHz. In the present disclosure, the “device for applying an electrical potential” may also be referred to as “electrical potential application device” or “charging device”. In the present disclosure, the expressions, “device for applying an electrical potential”, “electrical potential application device” and “charging device” may be used synonymously. Typically, the electrical potential application device is connected to the coating drum via a physical contact, e.g. an electrical contact. Accordingly, an electrical contact can be provided between the electrical potential application device and the coating drum. For instance, the electrical contact can be an electrical sliding contact or an electrical brush contact. According to another example, the electrical contact can be a plug contact. Accordingly, the device for applying an electrical potential to the coating drum as described herein can be understood as a charging device configured for providing an electrical charge to the coating drum.

The terms “upstream from” and “downstream from” as used herein may refer to the position of the respective chamber or of the respective component with respect to another chamber or component along the substrate transportation path. For example, during operation, the substrate is guided from the first spool chamber 110 through the deposition chamber 120 and subsequently guided to the second spool chamber 150 along the substrate transportation path via the roller assembly. Accordingly, the deposition chamber 120 is arranged downstream from the first spool chamber 110, and the first spool chamber 110 is arranged upstream from the deposition chamber 120. When, during operation, the substrate is first guided by or transported past a first roller or a first component and subsequently guided by or transported past a second roller or a second component, the second roller or second component is arranged downstream from the first roller or first component.

According to embodiments which can be combined with any other embodiments described herein, the device 140 for applying an electrical potential to the coating drum 122 is configured for applying an electrical potential having a middle frequency (MF), particularly a frequency of 1 kHz to 100 kHz. In other words, the electrical potential provided from the electrical potential application device can be an electrical potential having a frequency of 1 kHz to 100 kHz. In particular, a middle frequency electric potential can be understood as an electrical potential with an alternating polarity at a frequency selected from the range of 1 kHz to 100 kHz. It has been found that applying a MF electrical potential to the coating drum has the advantage that a charge up of the substrate, particularly of the layer deposited on the substrate, can substantially be avoided or even eliminated. Accordingly, layers with higher quality (e.g. higher uniformity, less defects, etc.) can be deposited on the substrate while at the same time beneficially the layers, for instance one or more carbon layers, can be densified.

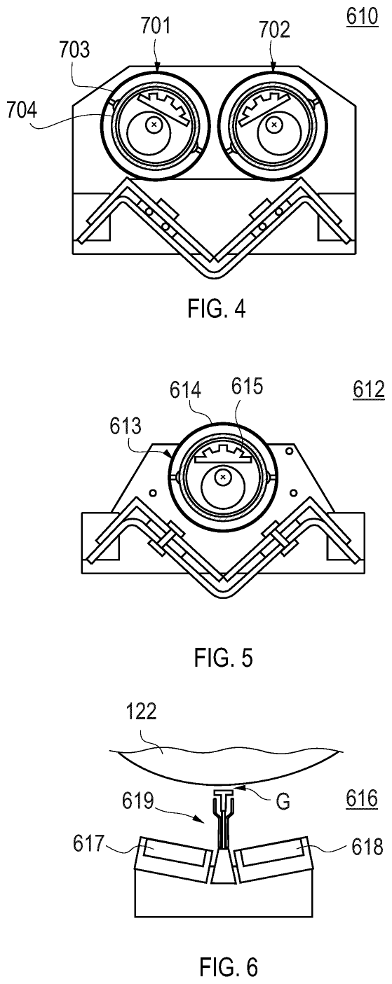

According to embodiments which can be combined with any other embodiments described herein, the at least one deposition unit 124 is a direct current sputter deposition unit. Alternatively, the at least one deposition unit 124 can be a pulsed direct current sputter deposition unit. As schematically shown in FIGS. 1 and 2, the graphite target 125 of the at least one deposition unit 124 can be a planar target. Alternatively, the graphite target 125 of the at least one deposition unit 124 can be a rotatable target. With exemplary reference to FIGS. 4, 5 and 6, various possible implementations of deposition units are described which may be used for the plurality of deposition units 121 as well as for the at least one deposition unit 124 having a graphite target 125 as described herein. Accordingly, alternatively to the schematic illustration in FIGS. 1, 2 and 3 of the at least one deposition unit 124 having a planar graphite target, the at least one deposition unit 124 may be configured as exemplarily described with exemplary reference to FIGS. 4, 5 and 6.

With exemplary reference to FIGS. 1 and 2, it is to be understood that typically the deposition apparatus 100 is configured such that the flexible substrate 10 can be guided from the first spool chamber 110 to the second spool chamber 150 along a substrate transportation path, wherein the substrate transportation path may lead through the deposition chamber 120. The flexible substrate can be coated with a stack of layers in the deposition chamber 120. A roller assembly comprising a plurality of rolls or rollers can be provided for transporting the substrate along the substrate transportation path, wherein two or more rollers, five or more rollers, or ten or more rollers of the roller assembly may be arranged between the storage spool and the wind-up spool.

According to some embodiments herein, which can be combined with any other embodiments described herein, the apparatus further includes a roller assembly configured to transport the flexible substrate along a partially convex and partially concave substrate transportation path from the first spool chamber to the second spool chamber. In other words, the substrate transportation path may be partially curved to the right and partially curved to the left such that some guiding rollers contact a first main surface of the flexible substrate and some guiding rollers contact a second main surface of the flexible substrate opposite the first main surface.

For example, the first guiding roller 107 in FIG. 2 contacts a second main surface of the flexible substrate and the flexible substrate is bent to the left while being guided by the first guiding roller 107 (“convex” section of the substrate transportation path). The second guiding roller 108 in FIG. 2 contacts a first main surface of the flexible substrate and the flexible substrate is bent to the right while being guided by the second guiding roller 108 (“concave” section of the substrate transportation path). Accordingly, beneficially a compact deposition apparatus may be provided.

According to some embodiments, some chambers or all chambers of the deposition apparatus may be configured as vacuum chambers that can be evacuated. For instance, the deposition apparatus may include components and equipment allowing for the generation of or maintenance of a vacuum in the first spool chamber 110 and/or the deposition chamber 120 and/or the second spool chamber 150. In particular, the deposition apparatus may include vacuum pumps, evacuation ducts, vacuum seals and the like for generating or maintaining a vacuum in the first spool chamber 110 and/or the deposition chamber 120 and/or the second spool chamber 150.

As exemplary shown in FIGS. 1 and 2, the first spool chamber 110 is typically configured to accommodate a storage spool 112, wherein the storage spool 112 may be provided with the flexible substrate 10 wound thereon. During operation, the flexible substrate 10 can be unwound from the storage spool 112 and transported along the substrate transportation path (indicated by the arrows in FIGS. 1 and 2) from the first spool chamber 110 toward the deposition chamber 120. The term “storage spool” as used herein may be understood as a roll on which a flexible substrate to be coated is stored. Accordingly, the term “wind-up spool” as used herein may be understood as a roll adapted for receiving the coated flexible substrate. The term “storage spool” may also be referred to as a “supply roll” herein, and the term “wind-up spool” may also be referred to as a “take-up roll” herein.

With exemplary reference to FIG. 2, according to embodiments which can be combined with any other embodiments descried herein, sealing devices 105 may be provided between adjacent chambers, e.g. between the first spool chamber 110 and the deposition chamber 120 and/or between the deposition chamber 120 and the second spool chamber 150. Accordingly, beneficially the winding chambers (i.e. the first spool chamber 110 and the second spool chamber 150) may be vented or evacuated independently, in particular independently from the deposition chamber. The sealing device 105 may include an inflatable seal configured to press the substrate against a flat sealing surface.

As exemplarily shown in FIG. 2, typically the coating drum 122 is configured for guiding the flexible substrate 10 past the plurality of deposition units, e.g. past a first deposition unit 121A, a second deposition unit 121B, and a third deposition unit 121C. For example, as schematically indicated in FIG. 2, the first deposition unit 121A and the third deposition unit 121C can be AC (alternating current) sputter sources, as exemplarily described in more detail with reference to FIG. 4. The second deposition unit 121B can be the at least one deposition unit 124 having the graphite target 125.

As exemplarily indicated by the arrow in FIG. 2, typically the coating drum 122 is rotatable around a rotation axis 123. In particular, the coating drum may be actively driven. In other words, a drive may be provided for rotating the coating drum. The coating drum may include a curved substrate support surface, e.g. an outer surface of the coating drum 122, for contacting the flexible substrate 10. In particular, the curved substrate support surface can be electrically conductive for providing an electrical potential as described herein. For instance, the substrate support surface may include or be made of an electrically conductive material, e.g. a metallic material.

Accordingly, during guiding of the flexible substrate by the coating drum past the plurality of deposition units, the flexible substrate may be in direct contact with the substrate support surface of the coating drum. For example, the deposition units of the plurality of deposition units may be arranged in a circumferential direction around the coating drum 122, as schematically illustrated in FIGS. 1, 2 and 3. As the coating drum 122 rotates, the flexible substrate is guided past the deposition units which face toward the curved substrate support surface of the coating drum, so that the first main surface of the flexible substrate can be coated while being moved past the deposition units at a predetermined speed.

Accordingly, during operation, the substrate is guided over the substrate guiding region on the curved substrate support surface of the coating drum. The substrate guiding region may be defined as an angular range of the coating drum in which the substrate is in contact with the curved substrate surface during the operation of the coating drum, and may correspond to the enlacement angle of the coating drum. In some embodiments, the enlacement angle of the coating drum may be 120° or more, particularly 180° or more, or even 270° or more, as is schematically depicted in FIG. 2. In some embodiments, an uppermost portion of the coating drum may not be in contact with the flexible substrate during operation, wherein the enlacement area of the coating drum may cover at least the entire lower half of the coating drum. In some embodiments, the coating drum may be enlaced in an essentially symmetric way by the flexible substrate.

According to some embodiments, which may be combined with other embodiments described herein, the coating drum 122 may typically have a width in the range from 0.1 m to 4 m, more typically from 0.5 to 2 m, e.g. about 1.4 m. The diameter of the coating drum may be more than 1 m, e.g. between 1.5 m and 2.5 m.

In some embodiments, one or more rollers, e.g. guiding rollers, of the roller assembly may be arranged between the storage spool 112 and the coating drum 122 and/or downstream from the coating drum 122. For example, in the embodiment shown in FIG. 1, two guiding rollers are provided between the storage spool 112 and the coating drum 122, wherein at least one guiding roller may be arranged in the first spool chamber and at least one guiding roller may be arranged in the deposition chamber upstream from the coating drum 122. In some embodiments, three, four, five or more, particularly eight or more guiding rollers are provided between the storage spool and the coating drum. The guiding rollers may be active or passive rollers.

An “active” roller or roll as used herein may be understood as a roller that is provided with a drive or a motor for actively moving or rotating the respective roller. For example, an active roller may be adjusted to provide a predetermined torque or a predetermined rotational speed. Typically, the storage spool 112 and the wind-up spool 152 may be provided as active rollers. In some embodiments, the coating drum may be configured as an active roller. Further, active rollers can be configured as substrate tensioning rollers configured for tensioning the substrate with a predetermined tensioning force during operation. A “passive” roller as used herein may be understood as a roller or roll that is not provided with a drive for actively moving or rotating the passive roller. The passive roller may be rotated by the frictional force of the flexible substrate that may be in direct contact with an outer roller surface during operation.

As exemplarily shown in FIG. 2, one or more guiding rollers 113 may be arranged downstream from the coating drum 122 and upstream from the second spool chamber 150. For example, at least one guiding roller may be arranged in the deposition chamber 120 downstream from the coating drum 122 for guiding the flexible substrate 10 toward the vacuum chamber, e.g. the second spool chamber 150, arranged downstream from the deposition chamber 120, or at least one guiding roller may be arranged in the second spool chamber 150 upstream from the coating drum 122 for guiding the flexible roller in a direction essentially tangential to the substrate support surface of the coating drum, in order to smoothly guide the flexible substrate onto the wind-up spool 152.

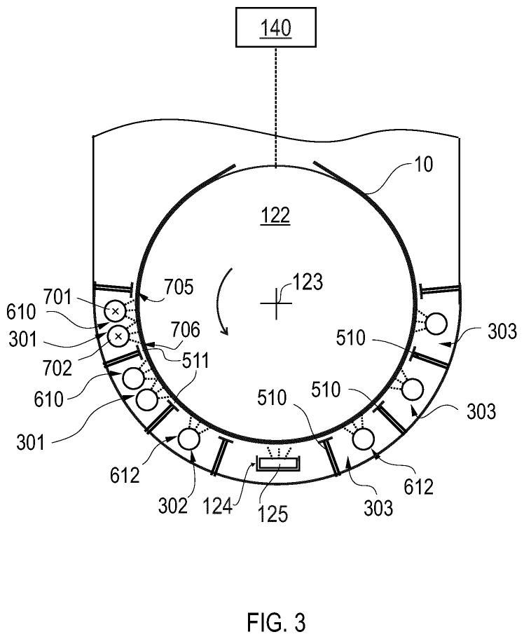

FIG. 3 shows an enlarged schematic view of a part of a deposition chamber that may be used in some of the embodiments described herein. According to some embodiments, which may be combined with other embodiments described herein, gas separation units 510 may be provided between two adjacent deposition units in order to reduce a flow of process gases from one deposition unit to other deposition units, e.g. to an adjacent deposition unit during operation, respectively. The gas separation units 510 may be configured as gas separation walls which divide the inner volume of the deposition chamber in a plurality of separate compartments, wherein each compartment may include one deposition unit. One deposition unit may be arranged between two neighboring gas separation units, respectively. In other words, the deposition units may be separated by the gas separation units 510, respectively. Accordingly, beneficially a high gas separation between neighboring compartments/deposition units can be provided.

According to embodiments, which can be combined with other embodiments described herein, each of the compartments which house a respective deposition unit can be evacuated independently from the other compartments housing other deposition units, such that the deposition conditions of the individual deposition units can be set as appropriate. Different materials can be deposited on the flexible substrate by adjacent deposition units which may be separated by gas separation units.

According to some embodiments, which can be combined with other embodiments described herein, the gas separation units 510 may be configured for adjusting a width of a slit 511 between the respective gas separation unit and the respective coating drum. According to some embodiments, the gas separation unit 510 may include an actuator configured for adjusting the width of the slit 511. In order to reduce the gas flow between adjacent deposition units and in order to increase the gas separation factor between adjacent deposition units, the width of the slit 511 between the gas separation units and the coating drum may be small, for example 1 cm or less, particularly 5 mm or less, more particularly 2 mm or less. In some embodiments, the lengths of the slits 511 in the circumferential direction, i.e. the length of the respective gas separation passages between two adjacent deposition compartments, may be 1 cm or more, particularly 5 cm or more, or even 10 cm or more. In some embodiments, the lengths of the slits may even be about 14 cm, respectively.

In some embodiments, which may be combined with other embodiments described herein, at least one first deposition unit of the plurality of deposition units 121 may be a sputter deposition unit. In some embodiments, each deposition unit of the plurality of deposition units 121 is a sputter deposition unit. Therein, one or more sputter deposition units may be configured for DC sputtering, AC sputtering, RF (radio frequency) sputtering, MF (middle frequency) sputtering, pulsed sputtering, pulsed DC sputtering, magnetron sputtering, reactive sputtering or combinations thereof. DC sputter sources may be suitable for coating the flexible substrate with conductive materials, e.g. with metals such as copper. Alternating current (AC) sputter sources, e.g. RF sputter sources or MF sputter sources, may be suitable for coating the flexible substrate with conductive materials or with isolating materials, e.g. with dielectric materials, semiconductors, metals or carbon.

However, the deposition apparatus described herein is not limited to sputter deposition, and other deposition units may be used in some embodiments. For example, in some implementations, CVD deposition units, evaporation deposition units, PECVD deposition units or other deposition units may be utilized. In particular, due to the modular design of the deposition apparatus, it may be possible to replace a first deposition unit with a second deposition unit by radially removing the first deposition unit from the deposition chamber and by loading another deposition unit into the deposition chamber. For that reason, the deposition chamber may be provided with sealed lids which may be opened and closed for replacing one or more deposition units.

In some embodiments, which can be combined with other embodiments described herein, at least one AC sputter source may be provided, e.g. in the deposition chamber, for depositing a non-conductive material on the flexible substrate. In some embodiments, at least one DC sputter source may be provided in the deposition chamber for depositing a conductive material or carbon on the flexible substrate.

According to an example as exemplarily shown in FIG. 3, which can be combined with other embodiments described herein, at least one first deposition unit 301 of the plurality of deposition units may be an AC sputter source. In the embodiment shown in FIG. 3, the first two deposition units of the plurality of deposition units are AC sputter sources, e.g. dual target sputter sources described below in more detail. A dielectric material such as silicon oxide may be deposited on the flexible substrate with the AC sputter sources. For example, two adjacent deposition units, e.g. the first deposition units, may be configured to deposit a silicon oxide layer directly on the first main surface of the flexible substrate in a reactive sputter process. The thickness of the resulting silicon oxide layer may be increased, e.g. doubled, by utilizing two or more AC sputter sources next to each other.

The remaining deposition units of the plurality of deposition units may be DC sputter sources. In the embodiment shown in FIG. 3, at least one second deposition unit 302 of the plurality of deposition units arranged downstream from the at least one first deposition unit 301 may be a DC sputter source, e.g. configured for depositing a carbon layer or an ITO layer. In other embodiments, two or more DC sputter sources configured for depositing a carbon layer or an ITO layer may be provided. In some embodiments, the carbon layer or the ITO layer may be deposited on top of the silicon oxide layer deposited by the at least one first deposition unit 301.

Further, in some embodiments, at least one third deposition unit 303 (e.g. three third deposition units) arranged downstream from the at least one second deposition unit 302, may be configured as a DC sputter unit, e.g. for depositing a metal layer. As exemplarily shown in FIG. 3, according to embodiments which can be combined with any other embodiments described herein, the at least one deposition unit 124 with the graphite target 125 can be arranged downstream from the at least one second deposition unit 302 and upstream from the at least one third deposition unit 303. For instance, as exemplarily shown in FIG. 3, a total of seven deposition units may be provided. However, it is to be understood that the deposition chamber configuration shown in FIG. 3 is an example and other configurations are possible, e.g. configurations with another sequential order of deposition units or another number of deposition units.

FIG. 4 shows the AC sputter source 610 in more detail, and FIG. 5 shows the DC sputter source 612 in more detail. The AC sputter source 610 shown in FIG. 4 may comprise two sputter devices, i.e. a first sputter device 701 and a second sputter device 702. In the present disclosure, a “sputter device” is to be understood as a device including a target 703 comprising a material to be deposited on the flexible substrate. The target may be made of the material to be deposited or at least of components of the material to be deposited. In some embodiments, a sputter device may include a target 703 configured as a rotatable target having a rotation axis. In some implementations, a sputter device may include a backing tube 704 on which the target 703 may be arranged. In some implementations, a magnet arrangement for generating a magnetic field during the operation of the sputter device may be provided, e.g. inside a rotatable target. In cases where a magnet arrangement is provided in the rotatable target, the sputter device may be referred to as a sputter magnetron. In some implementations, cooling channels may be provided within the sputter device in order to cool the sputter device or parts of the sputter device.

In some implementations, the sputter device may be adapted to be connected to a support of a deposition chamber, e.g. a flange may be provided at an end of the sputter device. According to some embodiments, the sputter device may be operated as a cathode or as an anode. For example, the first sputter device 701 may be operated as a cathode, and the second sputter device 702 may be operated as an anode at one point in time. When an alternating current is applied between the first sputter device 701 and the second sputter device 702, at a later point in time, the first sputter device 701 may act as an anode and the second sputter device 702 may act as a cathode. In some embodiments, the target 703 may include or be made of silicon.

The term “twin sputter device” refers to a pair of sputter devices, e.g. to the first sputter device 701 and the second sputter device 702. The first sputter device and the second sputter device may form a twin sputter device pair. For instance, both sputter devices of the twin sputter device pair may be simultaneously used in the same deposition process to coat the flexible substrate. Twin sputter devices may be designed in a similar way. For example, twin sputter devices may provide the same coating material, may substantially have the same size and substantially the same shape. The twin sputter devices may be arranged adjacent to each other to form a sputter source which may be arranged in a deposition chamber. According to some embodiments, which may be combined with other embodiments described herein, the two sputter devices of the twin sputter device include targets made of the same material, e.g. silicon, ITO, or carbon.

As can be seen in FIG. 3 and in FIG. 4, the first sputter device 701 has a first axis, which may be the rotation axis of the first sputter device 701. The second sputter device 702 has a second axis, which may be the rotation axis of the second sputter device 702. The sputter devices provide a material to be deposited on the flexible substrate. For reactive deposition processes, the material finally deposited on the flexible substrate can additionally include compounds of a processing gas.

According to the embodiment as exemplarily shown in FIG. 3, the flexible substrate is guided past the twin sputter devices by the coating drum 122. Therein, a coating window is limited by a first position 705 of the flexible substrate on the coating drum 122 and a second position 706 of the flexible substrate on the coating drum 122. The coating window, i.e. the portion of the flexible substrate between the first position 705 and the second position 706, defines the area of the substrate on which material may be deposited. As can be seen in FIG. 3, particles of the deposition material released from the first sputter device 701 and particles of the deposition material released from the second sputter device 702 reach the flexible substrate in the coating window.

The AC sputter source 610 may be adapted so as to provide a distance of the first axis of the first sputter device 701 to the second axis of the second sputter device 702 of 300 mm or less, particularly 200 mm or less. Typically, the distance of the first axis of the first sputter device 701 and the second axis of the second sputter device 702 may be between 150 mm and 200 mm, more typically between 170 mm and 185 mm, such as 180 mm. According to some embodiments, the outer diameter of the first sputter device 701 and of the second sputter device 701 which may be cylindrical sputter devices can be in the range of 90 mm and 120 mm, more typically between about 100 mm and about 110 mm.

In some embodiments, the first sputter device 701 may be equipped with a first magnet arrangement and the second sputter device 702 may be equipped with a second magnet arrangement. The magnet arrangements may be magnet yokes configured for generating a magnetic field to improve the deposition efficiency. According to some embodiments, the magnet arrangements may be tilted towards each other. The magnet arrangements being arranged in a tilted way towards each other may mean in this context that the magnetic fields generated by the magnet arrangements are directed towards each other.

FIG. 5 shows an enlarged schematic view of a DC sputter source 612 that may be used in some of the embodiments described herein. In some embodiments, the at least one second deposition unit 302 depicted in FIG. 3 is configured as a DC sputter source 612, and/or the at least one third deposition unit 303 is configured as a DC sputter source 612. The DC sputter source 612 may include at least one cathode 613 including a target 614 for providing the material to be deposited on the flexible substrate. The at least one cathode 613 may be a rotatable cathode, particularly an essentially cylindrical cathode, which may be rotatable around a rotation axis. The target 614 may be made of the material to be deposited. For example, the target 614 may be a metal target, such as a copper or an aluminum target. In embodiments in which the at least one deposition unit 124 is configured as a DC sputter source as exemplarily shown in FIG. 5, the target 614 is a graphite target. Further, as exemplarily shown in FIG. 5, a magnet assembly 615 for confining the generated plasma may be arranged inside the rotatable cathode.

In some implementations, the DC sputter source 612 may include a single cathode, as exemplarily shown in FIG. 5. In some embodiments, a conductive surface, e.g. a wall surface of the deposition chamber, may act as an anode. In other implementations, a separate anode, such as an anode having the shape of a rod, may be provided next to the cathode such that an electric field may build up between the at least one cathode 613 and the separate anode. A power supply may be provided for applying an electric field between the at least one cathode 613 and the anode. A DC-electric field may be applied which may allow for the deposition of a conductive material, such as a metal. In some implementations, a pulsed DC field is applied to the at least one cathode 613. In some embodiments, the DC sputter source 612 may include more than one cathode, e.g. an array of two or more cathodes.

According to some embodiments, which may be combined with other embodiments described herein, a deposition unit as described herein may be configured as a double DC planar cathode sputter source 616, as exemplarily shown in FIG. 6. For instance, the double DC planar cathode may include a first planar target 617 and a second planar target 618. The first planar target can include a first sputter material and the second planar target can include a second sputter material which is different from the first sputter material. According to some implementations, a protection shield 619 may be provided between the first planar target 617 and the second planar target 618, as exemplarily shown in FIG. 6. The protection shield may be attached, e.g. clamped, to a cooled part such that cooling of the protection shield can be provided. More specifically, the protection shield may be configured and arranged between the first planar target and the second planar target such that intermixing of the respective material provided from the first planar target and the second planar target can be prevented. Further, as exemplarily shown in FIG. 6, the protection shield can be configured such that a narrow gap G between the protection shield and a substrate on the coating drum 122 is provided. Accordingly, a double DC planar cathode can beneficially be configured for depositing two different materials. Typically, as described herein, a deposition unit including an AC sputter source 610, a DC sputter source 612, or a double DC planar cathode sputter source 616 is provided in a compartment as described herein, i.e. a compartment provided between two gas separation units 510 as described herein.

According to embodiments, which can be combined with other embodiments described herein, it is to be understood that the deposition units, particularly the cathodes (e.g. the AC sputter source, the DC-rotatable cathode, the twin rotatable cathode, and the double DC planar cathode) are interchangeable. Accordingly, a common compartment design may be provided. Further, the deposition units may be connected to a process controller which is configured to individually control the respective deposition unit. Accordingly, beneficially, a process controller may be provided such that the reactive process can be run fully automated.

According to some embodiments, which can be combined with any other embodiments described herein, a deposition source as described herein may be configured for a reactive deposition process. Further, a process gas may be added to at least one of the plurality of separate compartments in which the individual deposition units are provided. In particular, the process gas may be added to the compartment including the at least one deposition unit 124 having the graphite target 125. For example, the process gas can include at least one of argon, C₂H₂ (acetylene), CH₄ (methane) and H₂ (hydrogen). Providing a process gas as described herein can be beneficial for layer deposition, particularly for carbon layer deposition.

In view of the embodiments of the deposition apparatus as described herein, it is to be noted that a deposition apparatus 100 for coating a flexible substrate 10 with a stack of layers including a diamond like carbon layer is provided. According to embodiments which can be combined with any other embodiments described herein, the deposition apparatus 100 includes a first spool chamber 110 housing a storage spool 112 for providing the flexible substrate 10, a deposition chamber 120 arranged downstream from the first spool chamber 110, and a second spool chamber 150 arranged downstream from the deposition chamber 120 and housing a wind-up spool 152 for winding the flexible substrate 10 thereon after deposition. The deposition chamber 120 includes a coating drum 122 for guiding the flexible substrate past a plurality of deposition units 121 including at least one sputter deposition unit having a graphite target 125. The coating drum is configured for providing an electrical potential to a substrate guiding surface of the coating drum. For example, the substrate guiding surface of the coating drum can be subjected to an electrical potential by using an electrical potential application device as described herein. In particular, the electrical potential applied to the coating drum can be a middle frequency potential having a frequency of 1 kHz to 100 kHz.

In view of the embodiments described herein, it is to be understood that the apparatuses and methods are particularly well-suited for coating a flexible substrate with a stack of layers including at least one carbon layer. A “stack of layers” can be understood as two, three or more layers deposited on top of each other, wherein the two, three or more layers may be composed of the same material or of two, three or more different materials. For example, the stack of layers may include one or more carbon layers, particularly one or more diamond like carbon (DLC) layers. Further, the stack of layers may include one or more conductive layers, e.g. a metal layer, and/or one or more isolating layers, e.g. a dielectric layer. In some embodiments, the stack of layers may include one or more transparent layers, e.g. a SiO₂ layer or an ITO layer. In some embodiments, at least one layer of the stack of layers may be a conductive transparent layer, e.g. an ITO layer. For example, an ITO layer may be beneficial for capacitive touch applications, e.g. for touch panels.

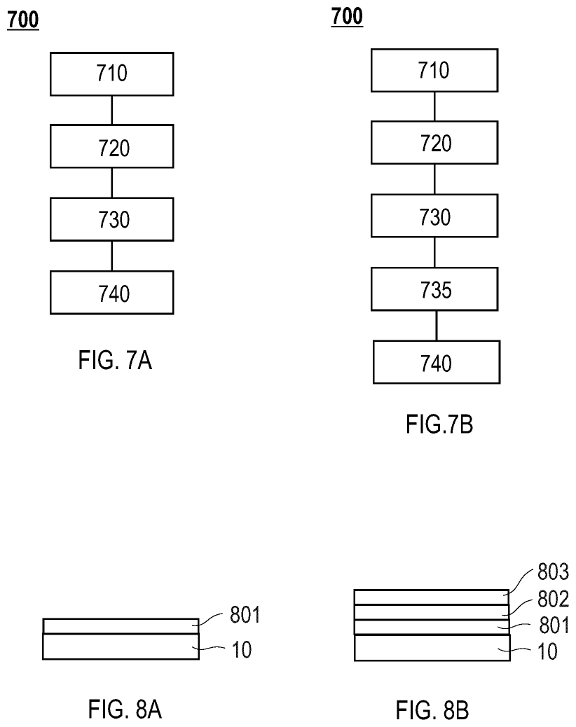

With exemplary reference to the flowcharts shown in FIGS. 7A and 7B, embodiments of a method 700 of coating a flexible substrate, particularly with a carbon layer, are described. According to embodiments which can be combined with any other embodiments described herein, the method 700 includes unwinding (block 710) the flexible substrate from a storage spool 112 provided in a first spool chamber 110. Further, the method 700 includes depositing (block 720) a carbon layer on the flexible substrate 10, while guiding the flexible substrate by a coating drum 122 provided in a deposition chamber 120. Typically, depositing the carbon layer on the flexible substrate includes depositing the carbon layer onto a layer previously deposited on the substrate. Alternatively, depositing the carbon layer on the flexible substrate may include depositing the carbon layer directly on the substrate. Additionally, as exemplarily indicated by block 730, the method includes applying an electrical potential to the coating drum. Typically, after deposition the method includes winding (block 740) the flexible substrate on a wind-up spool 152 provided in a second spool chamber 150.

According to embodiments which can be combined with any other embodiments described herein, applying (block 730) the electrical potential to the coating drum includes applying a middle frequency potential having a frequency of 1 kHz to 100 kHz. In particular, applying (block 730) the electrical potential to the coating drum may include using a device 140 for applying an electrical potential as described herein. As described above with reference to the embodiments of the deposition apparatus, it has been found that applying an MF electrical potential to the coating drum has the advantage that a charge up of the substrate, particularly of the layer deposited on the substrate, can substantially be avoided or even eliminated. Accordingly, layers (e.g. a carbon layer, particularly a DLC-layer) can be obtained.

According to embodiments which can be combined with any other embodiments described herein, depositing (block 720) the carbon layer includes sputtering by using a deposition unit having a graphite target. In particular, depositing (block 720) the carbon layer may include using at least one deposition unit 124 having a graphite target 125 as described herein. Further, depositing the carbon layer may include adding a process gas to the compartment including the at least one deposition unit 124 having the graphite target 125. For example, the process gas can include at least one of argon, C₂H₂ (acetylene), CH₄ (methane) and H₂ (hydrogen).

With exemplary reference to FIG. 7B, according to embodiments which can be combined with any other embodiments described herein, the method 700 further includes densifying (block 735) the carbon layer by ion bombardment and/or electron bombardment. In particular, densifying (block 735) the carbon layer by providing an ion bombardment and/or an electron bombardment can be achieved by accelerating electrons or ions, e.g. from a plasma provided in the deposition chamber 120, towards the coating drum 122 by providing the coating drum with an electrical potential, as described herein. Providing an ion bombardment and/or an electron bombardment on a deposited layer, particularly a deposited carbon layer, can include providing a plasma including ions and or electrons. Accordingly, beneficially a diamond like carbon (DLC) layer can be generated.

FIGS. 8A and 8B show a flexible substrate 10 being coated with one or more layers including at least one carbon layer being produced by a method of coating the flexible substrate according to embodiments described herein. Accordingly, it is to be understood that the flexible substrate can be coated with one, two, three, four, five, six, seven or more layers, wherein at least one layer is a carbon layer, particularity a DLC-layer, being produced by a method according to embodiments described herein. For instance, as exemplarily shown in FIG. 8A, the flexible substrate 10 can be coated with a first layer 801, the first layer being a carbon layer, particularly a DLC-layer. FIG. 8B shows a flexible substrate 10 being coated with a stack of layers including a first layer 801, a second layer 802 and a third layer 803, wherein at least one of the first layer 801, the second layer 802 and the third layer 803 is a carbon layer, particularly a DLC-layer produced by a method according to embodiments described herein. Accordingly, beneficially a flexible substrate can be provided with a layer stack deposited on the flexible substrate, wherein the layer stack includes at least one carbon layer, particularly a DLC-layer.

In view of the embodiments described herein, it is to be understood that compared to conventional deposition systems and methods, improved embodiments of a deposition apparatus and of a method of coating a flexible substrate are provided particularly with respect to the deposition of a carbon layer (e.g. a diamond like carbon (DLC) layer). More specifically, embodiments described herein beneficially provide for coating a flexible substrate with a stack of layers having one or more carbon layers (e.g. one or more DLC-layers).

While the foregoing is directed to embodiments, other and further embodiments may be devised without departing from the basic scope, and the scope is determined by the claims that follow.

1. A deposition apparatus for coating a flexible substrate, comprising:
a first spool chamber for housing a storage spool for providing the flexible substrate,
a deposition chamber arranged downstream from the first spool chamber, and
a second spool chamber arranged downstream from the deposition chamber and for housing a wind-up spool for winding the flexible substrate thereon after deposition,
the deposition chamber comprising a coating drum for guiding the flexible substrate past a plurality of deposition units including at least one deposition unit having a graphite target, the coating drum being connected to a device for applying an electrical potential to the coating drum.

2. The deposition apparatus of claim 1, wherein the electrical potential is a middle frequency potential having a frequency of 1 kHz to 100 kHz.

3. The deposition apparatus of claim 1, wherein the at least one deposition unit is a direct current sputter deposition unit.

4. The deposition apparatus of claim 1, wherein the at least one deposition unit is a pulsed direct current sputter deposition unit.

5. The deposition apparatus of claim 1, wherein the graphite target is a planar target.

6. The deposition apparatus of claim 1, wherein the graphite target is a rotatable target.

7. The deposition apparatus of claim 1, wherein the plurality of deposition units comprise at least one direct current sputter source configured for depositing a conductive material on the flexible substrate.

8. The deposition apparatus of claim 1, the coating drum being rotatable about a rotation axis, the coating drum comprising a curved substrate support surface for contacting the flexible substrate, the curved substrate support surface being electrically conductive.

9. The deposition apparatus of claim 1, further comprising a roller assembly configured to transport the flexible substrate along a partially convex and partially concave substrate transportation path from the first spool chamber to the second spool chamber.

10. A deposition apparatus for coating a flexible substrate with a stack of layers including a diamond like carbon layer, the apparatus comprising:
a first spool chamber for housing a storage spool for providing the flexible substrate,
a deposition chamber arranged downstream from the first spool chamber, and
a second spool chamber arranged downstream from the deposition chamber and for housing a wind-up spool for winding the flexible substrate thereon after deposition,
the deposition chamber comprising a coating drum for guiding the flexible substrate past a plurality of deposition units including at least one sputter deposition unit having a graphite target, the at least on deposition unit being a direct current sputter deposition unit, the graphite target being a planner target, the coating drum being configured for providing an electrical potential to a substrate guiding surface of the coating drum, the electrical potential being a middle frequency potential having a frequency of 1 kHz to 100 kHz.

11. A method of coating a flexible substrate with a carbon layer, the method comprising:
unwinding the flexible substrate from a storage spool provided in a first spool chamber;
depositing a carbon layer on the flexible substrate, while guiding the flexible substrate using a coating drum provided in a deposition chamber;
applying an electrical potential to the coating drum; and
winding the flexible substrate on a wind-up spool provided in a second spool chamber after deposition.

12. The method of claim 14, wherein applying the electrical potential to the coating drum comprises applying a middle frequency potential having a frequency of 1 kHz to 100 kHz.

13. The method of claim 14, wherein depositing the carbon layer comprises sputtering by using a deposition unit having a graphite target.

14. The method of claim 14, further comprising densifying the carbon layer by providing at least one of an ion bombardment and an electron bombardment.

15. A flexible substrate having a coating with one or more layers, wherein at least one layer is a carbon layer being produced by the method of coating a flexible substrate with a carbon layer, the method comprising:
unwinding the flexible substrate from a storage spool provided in a first spool chamber;
depositing a carbon layer on the flexible substrate, while guiding the flexible substrate using a coating drum provided in a deposition chamber;
applying an electrical potential to the coating drum; and
winding the flexible substrate on a wind-up spool provided in a second spool chamber after deposition.

16. The deposition apparatus of claim 2, wherein the at least one deposition unit (124) is a direct current sputter deposition unit.

17. The deposition apparatus of claim 1, wherein the plurality of deposition units comprises at least one AC sputter source for depositing a non-conductive material on the flexible substrate.

18. The deposition apparatus of claim 1, wherein the plurality of deposition units comprise at least one direct current sputter source configured for depositing a conductive material on the flexible substrate, and wherein the plurality of deposition units comprises at least one AC sputter source for depositing a non-conductive material on the flexible substrate.

19. The method of claim 11, wherein depositing the carbon layer comprises sputtering by using a direct current sputter deposition unit having a planar graphite target.

20. The flexible substrate of claim 15, wherein the carbon layer is a diamond like carbon layer.
